(19) United States
(12) Patent Application Publication
(10) Pub. No.: US 2010/0288332 A1
(43) Pub. Date: Nov. 18, 2010

(54) SOLAR PHOTOVOLTAIC CONCENTRATOR PANEL

(75) Inventor: Mark J. O'Neill, Keller, TX (US)

Correspondence Address: DUANE MORRIS LLP - Houston, 1330 POST OAK BLVD., SUITE 800, HOUSTON, TX, 77056, US

(73) Assignee: ENTECH SOLAR, INC., Fort Worth, TX (US)

(21) Appl. No.: 12/776,184

(22) Filed: May 7, 2010

Related U.S. Application Data
(60) Provisional application No. 61/177,498, filed on May 12, 2009.
(60) Provisional application No. 61/178,341, filed on May 14, 2009.

(51) Int. Cl. H01L 31/052

(52) U.S. Cl. 136/246

(57) ABSTRACT

A solar photovoltaic concentrator panel comprises a Fresnel lens concentrator which may be arched and a photovoltaic receiver within a container comprising a top window. The lens, photovoltaic cell, and window may be affixed in a container with no internal sun-tracking mechanisms or related internal moving parts such as motors, drive systems, or bearings. The window is transparent and the bottom of the container typically dimensioned and configured as a heat exchanger to passively dissipate waste heat from the photovoltaic receiver to the ambient environment. The Fresnel lens concentrator is typically a free-standing Fresnel lens concentrator disposed within the container at a fixed position relative to an interior dimension of the container, optically forming a focal region of concentrated sunlight. The photovoltaic receiver comprises a photovoltaic cell or group of such cells disposed within the container and attached to the bottom at a fixed position relative to an interior dimension of the container to maintain alignment of a predetermined portion of the photovoltaic receiver within the focal region of the free-standing Fresnel lens concentrator.

### PRIORITY INFORMATION

This application claims priority from U.S. Provisional Patent Application No. 61/177,498 filed on May 12, 2009 and U.S. Provisional Patent Application No. 61/178,341 filed on May 14, 2009.

### FIELD OF THE INVENTION

The invention relates generally to solar energy collection and conversion, and specifically to solar photovoltaic concentrators.

### BACKGROUND OF THE INVENTION

Much of current solar photovoltaic concentrator technology involves use of large, cumbersome, heavy, and, because of their size and bulk, relatively expensive solar panels. Most photovoltaic concentrators use either flat Fresnel lenses and/or parabolic mirrors to focus sunlight onto silicon or multi-junction photovoltaic cells.

A better optical approach is to use Fresnel lenses, which can be arched or domed, to focus sunlight onto the photovoltaic cells, since the optical advantages of arched or domed lenses over flat Fresnel lenses or mirrors are many and are well known to those of ordinary skill in the art of photovoltaic concentrator technology. However, current solar panels using large, arched Fresnel lenses are nonetheless bulky, heavy, and require large heat sinks. If the arched lens comprises an acrylic plastic, which is the presently preferred material, these acrylic lenses are flammable and can be damaged due to exposure to weather and environmental elements such as hail, wind, blowing sand, and the like. Furthermore, acrylic lens material allows water vapor to diffuse through the lens into the interior of the concentrator panel, where condensation can cause optical (condensation on the lens) and electrical (condensation on the cell circuit) problems.

### DRAWINGS

FIG. 1 is a view in partial perspective of an exemplary photovoltaic concentrator panel;

FIG. 2 is a view in partial perspective cut-away of a close-up exploded view of a portion of an exemplary photovoltaic concentrator panel;

FIG. 3 is a diagrammatic view of ray trace vectors of an exemplary embodiment;

FIG. 4 is a view in partial perspective cut-away of an exemplary embodiment with Fresnel lens supports with one exemplary Fresnel lens and its support ends shown in exploded view above the container;

FIG. 5 is a view in partial perspective cut-away of an exemplary embodiment with Fresnel lens supports; and

FIG. 6 is a view in partial perspective cut-away of an exemplary photovoltaic receiver assembly.

### BRIEF DESCRIPTION OF PREFERRED EMBODIMENTS

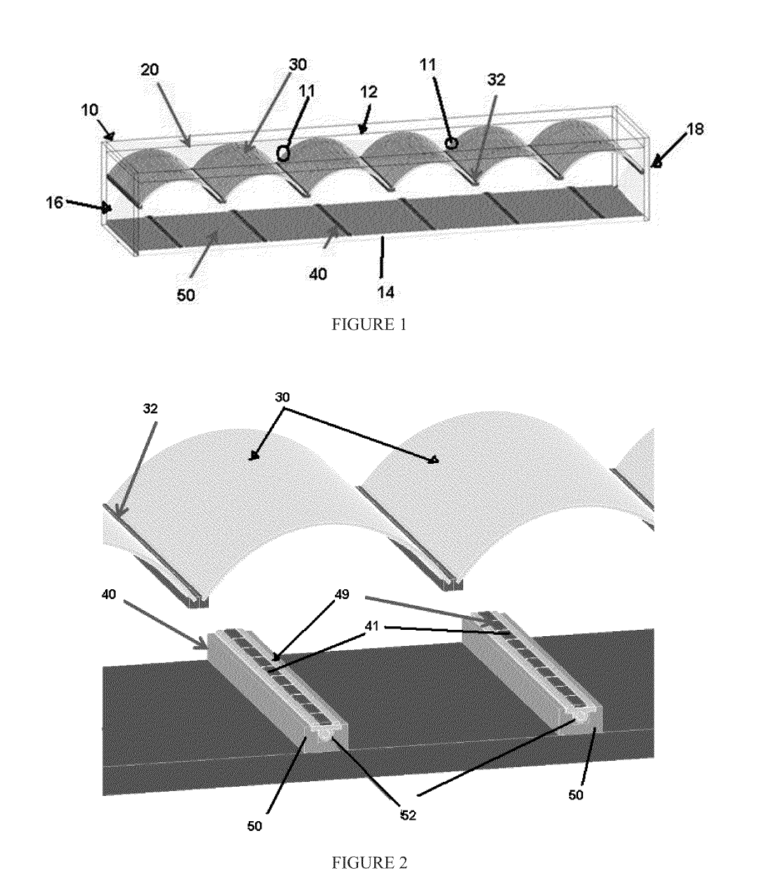

Referring now to FIG. 1, in an embodiment, photovoltaic concentrator panel 1 comprises container 10, one or more windows 20, one or more Fresnel lens concentrators 30, and one or more receivers 40. In certain embodiments, photovoltaic concentrator panel 1 further comprises one or more radiators 50.

Container 10 comprises top 12, sides 15-18, and bottom 14. Sides 15 and 17 (FIG. 4) may be (and are typically) configured as end plates attached to sides 16 and 18 and used to close out container 10. In one preferred embodiment, end plates 15 and 17, sides 16 and 18, and bottom 14 comprise a single-piece formed aluminum unit resembling a rectangular pan with an open top. Note that in FIG. 4, end plate 15 is not shown directly as FIG. 4 is a cutaway view of container 10.

In certain contemplated embodiments, bottom 14 comprises an aluminum radiator sheet. However, the container material is in no way restricted to aluminum, since many other materials such as galvanized steel, plastics, glass, or the like, or a combination thereof could be used.

As typically configured, container 10 comprises a weatherproof enclosure, with water-tight joints or seals between the exterior components, including top 12, sides 16 and 18, bottom 14, and end plates 15 and 17 (FIG. 4). Configured in this manner, container 10 is suited for allowing the mounting of electronic circuits and/or components within container 10, these electronic components typically representing balance-of-system elements as may be found in typical solar power systems. In certain embodiments, these electronic circuits and components may be mounted to one or more of the inner surfaces of container 10 and be operatively interconnected to each other and to receivers 40 to provide useful balance-of-system functionality, such as DC-to-DC voltage converters, DC-to-AC inverters, sun-tracking controllers which may comprise an open-loop microprocessor-based unit, or the like, or combinations thereof. Internal mounting of these electronic components can save cost at the system level by eliminating the need for weatherproof junction boxes for these components and by allowing factory installation of these electronic components inside container 10, rather than field assembly of these electronic components.

In certain contemplated embodiments, container 10 may also include one or more breathing ports 11, which provides a fluid conduit between the interior of container 10 and the outside environment and is dimensioned to help prevent a pressure differential between an interior portion of container 10 and the outside air.

In preferred embodiments, top 12 comprises a transparent material which defines window 20. Typically, window 20 comprises a glass with typical dimensions of around 1 meter wide by around 1.5 meters long. In currently contemplated embodiments, window 20 may comprise a glass coated with an anti-reflection (AR) coating on one or both of its surfaces, minimizing the optical transmittance loss for solar rays passing through the glass. For example, an inexpensive sol-gel coating on both glass surfaces can achieve 96% net transmittance for low-iron, tempered float glass with a thickness of around 3 mm. The window material is in no way restricted to glass, since any transparent material, such as plastic sheet or film, could serve the same function. For example, in alternative, lighter weight embodiments, window 20 may comprise a polymer sheet, such as acrylic plastic, a polymer film such as ETFE or FEP fluoropolymer material, a laminated combination of glass and polymer materials, or the like, or a combination thereof.

Window 20 may be coextensive with all of top 12 or comprise a predetermined portion of top 12 such as being disposed within a glass mounting frame (not shown in the figures) that is at least coextensive with top 12.

In currently preferred embodiments, window 20 is not a lens and does not contain any lens features, serving instead to allow incident light into container 10 and to protect Fresnel lens concentrator 30, receiver 40, and other interior components from exposure to weather elements such as rain, hail, blowing sand, dirt, and wind.

End plates 15 and 17 (FIG. 4) and sides 16 and 18 can comprise any suitable material, preferably non-flammable, such as a metal or glass.

Referring additionally to FIG. 2, Fresnel lens concentrators 30 are typically acrylic or other polymeric Fresnel lens concentrators 30 which are attached to lens support such as lens carrier 32 or other lens supports such as end supports 19a and 19b (FIG. 4) such that there is typically one such Fresnel lens concentrator 30 per receiver 40. As discussed herein below, receiver 40 comprises one or more photovoltaic cell circuits 49 which are typically a linear array of a plurality of operatively interconnected photovoltaic cells 41. In a further typical embodiment, Fresnel lens concentrators 30 are arched. An important feature of Fresnel lens concentrator 30 is that it is thin, lightweight, and economical to produce. In a preferred embodiment, the lens is a flexible, arched, acrylic or other polymeric symmetrical-refraction Fresnel lens about 0.25 mm thick and made by a continuous roll-to-roll process, such as lens film embossing. Such lens film is typically made in flat form and delivered on rolls and have relatively small dimensions (e.g., around 16 cm aperture width, 14 cm focal length, and 160 cm aperture length). For use in the present invention, the lens film is typically first trimmed to final size and then mechanically bent or thermally formed into the arched shape and attached to lens carrier 32 or other lens supports such as 19a, 19b. However, shapes other than arched may be used, provided they conform to the teachings herein.

Using an array of small Fresnel lens concentrators 30 allows photovoltaic concentrator panel 1 to have a depth of only a few inches versus a conventional concentrating photovoltaic module depth of 2-3 feet. This can save costs such as for enclosure materials, packaging/shipping cost, and/or installation cost.

A further important feature of Fresnel lens concentrator 30 is that it is mounted within container 10 independently of window 20. Thus, in typical installations, Fresnel lens concentrators 30 and receivers 40 are configured as independent pairs with self-aligning supports which are not connected to window 20, i.e. one Fresnel lens concentrator 30 is paired with one specific receiver 40. It is understood that there can be a plurality of paired Fresnel lens concentrators 30 and corresponding photovoltaic cell circuits 49 within container 10.

If photovoltaic concentrator panel 1 uses dome lens concentrators 30 and multi-junction photovoltaic cells 41, the dome lens design may further include color-mixing features as are known in the art. Container 10, including window 20 and bottom 14 dimensioned and configured to act as a heat rejection structure, can be adapted to a number of different photovoltaic concentrator configurations using free-standing lens concentrators 30 of various geometries focusing onto photovoltaic cells 41 of various types. The lens concentrator material is in no way restricted to acrylic or other polymeric plastic, since lens concentrators 30 could be made of any transparent moldable material, such as clear silicone materials.

Referring additionally to FIG. 4, in typical embodiments, Fresnel lens concentrator 30 is not bonded to window 20. In currently contemplated embodiments, each Fresnel lens concentrator 30 is secured along a predetermined border into lens carrier 32, if side support is used, or along its ends, if end supports such as end supports 19a and 19b are used. If side support is used, each lens carrier 32 is supported at its ends, or incrementally along its length, to maintain its position relative to the center of photovoltaic cell circuit 49, thereby ensuring that the focal line produced by Fresnel lens concentrator 30 remains centered on photovoltaic cell circuit 49. If end supports 19a, 19b are used, the need for the lens carrier 32 is eliminated by replacing lens carriers 32 with end supports 19a and 19b. In a preferred embodiment, supporting each Fresnel lens concentrator 30 in alignment with each receiver 40 and/or its photovoltaic cell circuit 49 is made possible by separating the individual Fresnel lens concentrators 30 from window 20.

Referring additionally to FIG. 6, with respect to receiver 40, one or more photovoltaic cells 41 are assembled into photovoltaic cell circuit 49 and attached to carrier 42 (FIG. 6) which may serves as a mounting surface for photovoltaic cells 41 and may also contain layers which serve as an electrical insulator to prevent shorting of photovoltaic cells 41 to bottom 14 (FIG. 1) of photovoltaic concentrator panel 1 (FIG. 1). These photovoltaic cells 41 are typically silicon solar cells and typically around 0.8 cm wide which may be made by conventional low-cost mass-production processes widely used in the one-sun solar cell industry. The solar cell material is in no way restricted to silicon, since many other cell materials from gallium arsenide (GaAs) to copper indium gallium selenide (CIGS) to triple-junction gallium indium phosphide-gallium arsenide-germanium (GaInP-GaAs-Ge) could be used.

Typically, receivers 40 are fully encapsulated and dielectrically isolated and capable of high-voltage operation for decades with no ground faults (shorts to the heat rejection structures). Carrier 42 may act as a substrate and may comprise a flex circuit or printed circuit board or other electronic circuit element, as is well known to those of ordinary skill in the art of assembling photovoltaic cell circuits or other types of electronic circuits. In one preferred embodiment, carrier 42, acting as an electrical insulator, may include one or more independent dielectric film layers 46, each made of a high-voltage insulation material such as polyimide, disposed below photovoltaic concentrator cell circuit 49. Two or more independent dielectric film layers 46 are preferred to prevent insulation breakdown due to a pinhole or other defect in one dielectric film layer 46.

Still referring to FIG. 6, in its simplest form, as further clarification of the preferred embodiment of receiver 40, receiver 40 may comprise one or more photovoltaic concentrator cell circuits 49. Each photovoltaic cell circuit 49 typically comprises one or more photovoltaic cells 41 which are electrically interconnected using electrical conduit 49a. Each electrical conduit 49a is typically a copper or other metallic strip operatively in electrical communication with the top surface of one photovoltaic cell 41 and the bottom surface of a neighboring photovoltaic cell 41, thereby joining these two photovoltaic cells 41 in series electrically. This pattern typically repeats along photovoltaic cell circuit 49 until photovoltaic cell circuit 49 is completed with one or more insulated copper end wires 48 exiting photovoltaic receiver 40 at each end of photovoltaic cell circuit 49.

Carrier 42, typically a strip of aluminum, is used to support photovoltaic cell circuit 49. Photovoltaic concentrator cell circuit 49 is typically adhesively bonded to first adhesive layer 45. Dielectric film layer 46 may be present and adhesively bonded to second adhesive layer 47 which is then bonded to carrier 42. Carrier 42 may be attached to bottom 14 of container 10 using any suitable means such as by a further adhesive layer.

In a preferred embodiment, the layers beneath photovoltaic cell circuit 49 comprise thermally loaded adhesive layer 45, further comprising a silicone material such as alumina-loaded Dow Corning Sylgard® 184; dielectric film layer 46, further comprising one or more laminated layers of polyimide material such as DuPont Kapton® CR, where two such layers are preferred; and adhesive layer 47, further comprising a thermally loaded silicone such as alumina-loaded Dow Corning Sylgard® 184. Where dielectric layer 46 comprises redundant layers of polyimide, these provide added durability and reliability in case of a defect such as an air bubble or void in one of the layers

For ease of handling and assembly, photovoltaic cell circuit 49 can be bonded to dielectric film layer 46 using a thermally loaded adhesive in first adhesive layer 45 and then bonded to carrier 42 using a second thermally loaded adhesive layer 47, and carrier 42 which is itself attached to bottom 14 of container 10 using another layer, e.g. a third layer, of thermally loaded adhesive.

Encapsulating layer 43 is attached to a top portion of photovoltaic cell circuit 49, and one or more prism covers 44 are attached to encapsulating layer 43 to aid in focusing incident light energy onto photovoltaic cell circuit 49. In a preferred embodiment, clear encapsulating layer 43 comprises silicone material, such as Dow Corning Sylgard® 184, and prismatic cell cover 44 comprises silicone material such as Dow Corning Sylgard 184®. In preferred embodiments, prismatic cell cover 44 reduces the shadowing loss of metal gridlines on the top surface of photovoltaic cells 41 by refracting focused sunlight away from these gridlines onto active solar cell material instead. Prismatic cell cover 44 is typically molded into or attached to clear encapsulating layer 43 over each photovoltaic cell 41 to eliminate gridline shadowing loss.

Referring back to FIG. 2, in another embodiment, photovoltaic cell circuit 49 is further mounted on heat sink 50 which acts as a thermal conduit as well as a support for photovoltaic cell circuit 49. In certain of these contemplated embodiments, each heat sink 50 further comprises fluid conduit 52, either of which comprises a substantially flat upper surface to which one or more photovoltaic cell circuits 49 are mounted. In a preferred one of these embodiments, fluid conduit 52 is at least partially disposed internally within heat sink 50. In these embodiments, heat sink 50 is adapted to transfer waste heat from receiver 40 into fluid within fluid carrier 52. Such fluid may be in the form of a liquid such as propylene glycol-water solution, or may be in the form of a liquid-to-vapor phase change fluid serving, for example, as a heat pipe. Additionally, the liquid may be pumped through fluid carrier 52 by use of an auxiliary pump (not shown in the figures). Adequate waste heat rejection may alternatively be via passive air-cooling, such as by using a thin aluminum back sheet radiator, e.g., 1 mm thick. It is currently contemplated that an air-cooled version of the invention will be used for electricity production alone while a liquid-cooled version will be used for combined electricity and heat production.

Waste heat may therefore be efficiently collected by insulating heat sink 50 to minimize heat losses to the environment and also by delivering the heat absorbed by the fluid to a nearby heat load, such as may be appropriate for use as hot water for an industrial or commercial application. The insulation material can also wrap around the sides and top edges of heat sink 50, leaving only the active solar cell material of receiver 40 exposed to the focus of Fresnel lens concentrator 30. If multiple heat sinks 50 are used in photovoltaic concentrator panel 1, corresponding to multiple photovoltaic cell circuits 49 under multiple Fresnel lens concentrators 30, fluid carriers 52 can be connected to insulated manifolds or other insulated fluid distribution system elements at the ends of the photovoltaic concentrator panel 1, using materials and designs well known to those of ordinary skill in the art in solar heat collection. In one embodiment, the thermal insulation material comprises an isocyanurate foam or other thermally insulating foam, materials well know to those of ordinary skill in the art of solar heat collection.

In some of these embodiments, when the waste heat generated within receiver 40 is to be dissipated to the surroundings, bottom 14 also acts as a heat exchanger and comprises a thermally conductive material, e.g., aluminum, which acts as a heat sink for receiver 40 as well as for transferring the waste heat to the surroundings such as by convection and radiation. Thus, in these embodiments bottom 14 may act as a backplane radiator for ambient air-cooling. To minimize the radiator temperature for the air-cooling approach, the surfaces of the backplane radiator should be reflective of solar wavelengths and absorptive/emissive of infrared wavelengths, which can be achieved with clear anodizing of aluminum or with white paint.

In another preferred embodiment of these embodiments, when the waste heat generated within receiver 40 is to be collected and used, bottom 14 comprises a low-cost, durable enclosure bottom made of a material such as glass or a suitable metal which may also act as a support for a thermally insulated, liquid-cooled receiver 40. A glass back material has an additional advantage of allowing diffuse sunlight to be transmitted completely through top 12 and bottom 14 of photovoltaic concentrator panel 1, reducing both the temperature of Fresnel lens concentrators 30 inside photovoltaic concentrator panel 1 and the external surfaces of photovoltaic concentrator panel 1.

Moreover, the configuration and relatively small size of receiver 40 is amenable to use of high-quality, proven solar cell and semiconductor circuit assembly fabrication equipment and methods and can be fully automated, producing assemblies at a higher-speed and lower cost and better quality.

Small receiver 40 or photovoltaic cell circuit 49 assemblies are more efficient than large receiver 40 or photovoltaic cell circuit 49 assemblies, due to the smaller currents and the smaller distances that the currents must be conducted, making the disclosed receivers 40 more efficient than receivers 40 in conventional larger concentrating photovoltaic modules. Further, small apertures make waste heat rejection simpler and less costly, due to the small quantity of waste heat and the small distances this waste heat needs to be conducted for dissipation, resulting in lower cell temperatures and higher cell efficiencies than for conventional larger concentrating photovoltaic modules

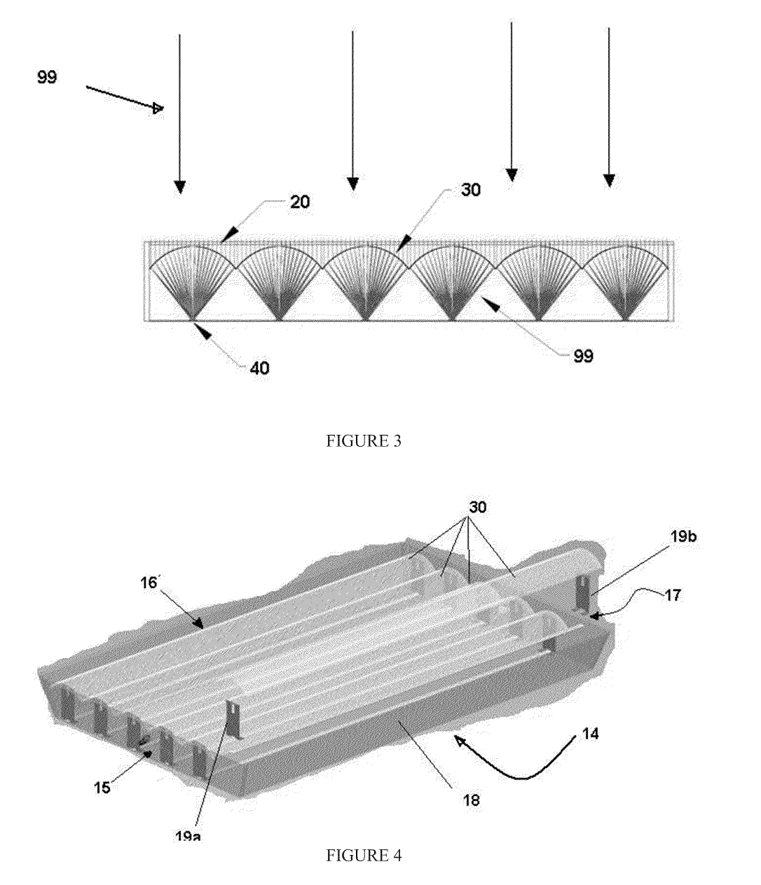

Referring now to FIG. 3, as further clarification of photovoltaic concentrator panel 1 functionality, the ray trace diagram in FIG. 3 illustrates the path of solar rays 99, first through window 20, then focused by Fresnel lens concentrators 30, and finally absorbed and converted into useful energy by photovoltaic cell circuits 49 in receiver 40 (FIG. 2).

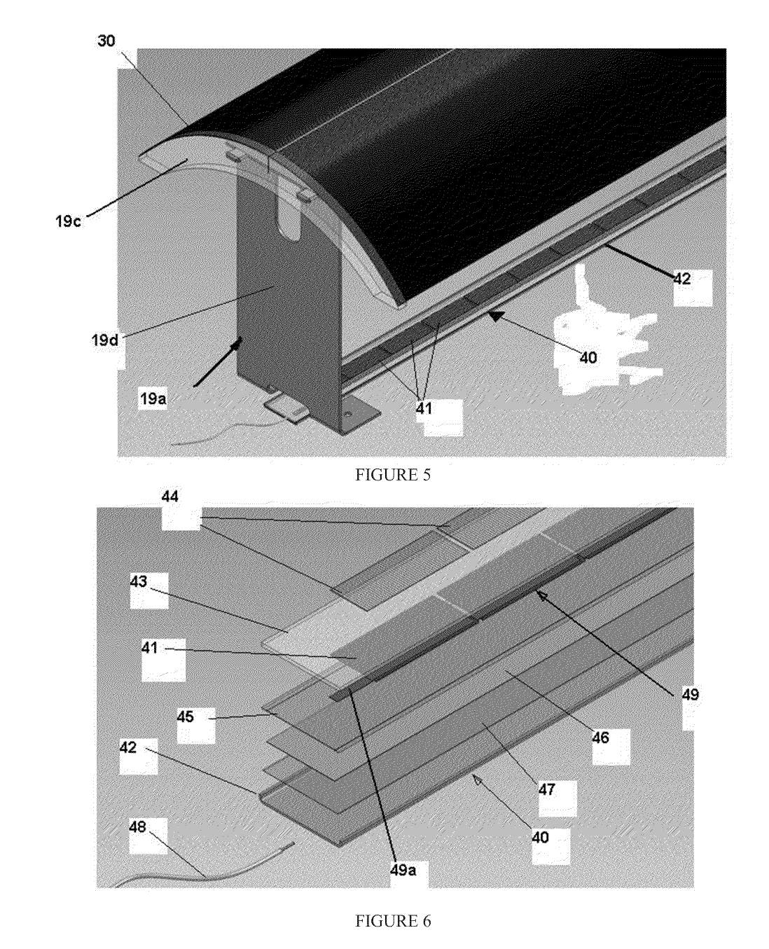

Referring now to FIGS. 4-5, as further clarification of the construction of one preferred embodiment of photovoltaic concentrator panel 1, each Fresnel lens concentrator 30 is supported by one or more end arches 19a, 19b which are attached to bottom 14. In a preferred embodiment, the attachment is via simple metal springs, e.g. 19d, which apply a slight tension force to Fresnel lens concentrator 30 to keep it substantially straight and in proper position by applying an outward force to upper arch attachment 19c which is bonded to lens 30, thereby applying a lengthwise tensioning force to lens 30.

Referring now to FIG. 5, as further clarification of the details in certain embodiments for each end arch 19a and its relationship with photovoltaic cell circuit 49 in receiver 40, where photovoltaic cell circuit 49 is aligned to the focal line of arched Fresnel lens concentrator 30, one preferred embodiment is shown whereby carrier 42 serves to support receiver 40 and is configured to self-align with a feature of end arch 19a. Such self-alignment of an individual Fresnel lens concentrator 30 with its paired photovoltaic cell circuit 49 is only possible when Fresnel lens concentrator 30 is not attached to window 20 (FIG. 1).

The foregoing disclosure and description of the inventions are illustrative and explanatory. Various changes in the size, shape, and materials, as well as in the details of the illustrative construction and/or illustrative method may be made without departing from the spirit of the invention. For example, while the above illustrations and descriptions have been directed to include line-focus arched Fresnel lenses and silicon cells arranged in linear photovoltaic receivers in the focal lines of the arched lenses, the spirit of the invention applies equally to point-focus dome-shaped lenses and multi-junction cells arranged in a pattern corresponding to the focal spots of the dome lenses.

What is claimed is:

1. A solar photovoltaic concentrator panel, comprising:
a. a container, the container further comprising:
i. a top, the top comprising a transparent window; and
ii. a bottom, the top and the bottom defining a plurality of ends; and
b. a free-standing Fresnel lens concentrator disposed within the container at a fixed position relative to an interior dimension of the container, the Fresnel lens concentrator refracting incident sunlight into a predetermined focal region within the container; and
c. a photovoltaic receiver disposed within the container and attached to the bottom within a predetermined portion of the focal region, the photovoltaic receiver comprising a photovoltaic cell.

2. The solar photovoltaic concentrator panel of claim 1, wherein the window is dimensioned and configured to allow incident light into the container and to protect the Fresnel lens and the photovoltaic receiver from exposure to a predetermined set of weather elements, the window otherwise not comprising any lens features.

3. The solar photovoltaic concentrator panel of claim 1, wherein the window comprises a glass.

4. The solar photovoltaic concentrator panel of claim 3, wherein the glass further comprises an anti-reflection coating on a predetermined side of the window.

5. The solar photovoltaic concentrator panel of claim 3, wherein the glass is around 1 meter wide by around 1.5 meters long.

6. The solar photovoltaic concentrator panel of claim 1, wherein the window is coextensive with all of the top.

7. The solar photovoltaic concentrator panel of claim 1, wherein the window comprises a transparent polymer.

8. The solar photovoltaic concentrator panel of claim 1, wherein the container is dimensioned and configured to be substantially weather-proof.

9. The solar photovoltaic concentrator panel of claim 1, wherein the photovoltaic concentrator panel further comprises:
a. a side disposed intermediate the top and the bottom; and
b. an end plate attached to the side.

10. The solar photovoltaic concentrator panel of claim 9, wherein the container further comprises a water-tight seal disposed intermediate the top, bottom, and side.

11. The solar photovoltaic concentrator panel of claim 10, wherein the container further comprises a water-tight seal disposed intermediate the top and bottom.

12. The solar photovoltaic concentrator panel of claim 9, wherein the top, bottom, side, and end plate comprise a non-flammable material.

13. The solar photovoltaic concentrator panel of claim 9, wherein:
a. the side is a plurality of sides;
b. the end plate is a plurality of end plates; and
c. the sides and end plates are dimensioned and configured to close out the container.

14. The solar photovoltaic concentrator panel of claim 13, wherein the container further comprises a single-piece of sheet metal forming the top, bottom, sides, and end plates of the container as a single unit.

15. The solar photovoltaic concentrator panel of claim 1, wherein the photovoltaic receiver is mounted to a predetermined inner surface of the container.

16. The solar photovoltaic concentrator panel of claim 1, wherein the photovoltaic receiver comprises a plurality of photovoltaic receivers.

17. The solar photovoltaic concentrator panel of claim 1, further comprising a predetermined electronic component operatively interconnected to the photovoltaic receiver.

18. The solar photovoltaic concentrator panel of claim 17, wherein the electronic component comprises at least one of a DC-to-DC voltage converter, a DC-to-AC inverter, and a sun-tracking controller.

19. The solar photovoltaic concentrator panel of claim 1, wherein the container further comprises a conduit between at an external surface and the interior of the container, the conduit dimensioned and configured to prevent a pressure differential between the interior of the container and outside air.

20. The solar photovoltaic concentrator panel of claim 1, wherein:
a. the Fresnel lens concentrator is arched; and
b. the arched Fresnel lens concentrator is attached to a lens carrier.

21. The solar photovoltaic concentrator panel of claim 20, wherein:
a. the lens carrier comprises a plurality of lens carriers, each further comprising an end arch; and
b. the arched Fresnel lens concentrator is attached to two end arches.

22. The solar photovoltaic concentrator panel of claim 21, wherein the arched Fresnel lens concentrator is a plurality of attached arched Fresnel lens concentrators dimensioned and configured such that there is one arched Fresnel lens concentrator per photovoltaic receiver.

23. The solar photovoltaic concentrator panel of claim 1, wherein the Fresnel lens concentrator comprises an acrylic and is around 0.25 mm thick and made by a continuous roll-to-roll process.

24. The solar photovoltaic concentrator panel of claim 1, wherein the Fresnel lens concentrator is mounted within the container independently of the window and is not bonded to the window.

25. The solar photovoltaic concentrator panel of claim 1, wherein:
a. the Fresnel lens concentrator is secured along a predetermined border of the Fresnel lens concentrator into a lens carrier; and
b. the lens carrier is supported at its ends or incrementally along its length to maintain its position relative to the center of the photovoltaic receiver, thereby ensuring that the focal line produced by the Fresnel lens concentrator remains centered on the photovoltaic receiver.

26. The solar photovoltaic concentrator panel of claim 1, wherein each Fresnel lens concentrator is separated from the window.

27. The solar photovoltaic concentrator panel of claim 1, further comprising:
a. a lens support disposed proximate each of the plurality of ends;
b. wherein
i. the Fresnel lens concentrator is secured at each of the plurality of ends to the lens supports; and
ii. the lens supports are dimensioned and configured to provide a tension force to support the Fresnel lens concentrator as a tensioned member and maintain a position of the Fresnel lens concentrator relative to a center of the photovoltaic receiver,
iii. whereby a focal line produced by the Fresnel lens concentrator remains substantially centered on the photovoltaic receiver.

28. The solar photovoltaic concentrator panel of claim 1, wherein:
a. the photovoltaic receiver comprises a plurality of photovoltaic cells operatively interconnected into a photovoltaic cell circuit; and
b. the photovoltaic receiver is attached to a carrier which serves as the mounting surface for the photovoltaic cells.

29. The solar photovoltaic concentrator panel of claim 28, wherein the carrier is dimensioned and configured to serve as an electrical insulator that prevents shorting of the photovoltaic cell to the bottom of the photovoltaic concentrator panel.

30. The solar photovoltaic concentrator panel of claim 28, wherein the carrier comprises at least one of a flex circuit or a printed circuit board.

31. The solar photovoltaic concentrator panel of claim 28, wherein the carrier comprises a plurality of independent dielectric film layers disposed below the photovoltaic concentrator cell circuit.

32. The solar photovoltaic concentrator panel of claim 1, wherein the photovoltaic receiver is mounted on a heat exchanger attached to the bottom.

33. The solar photovoltaic concentrator panel of claim 32, wherein the heat exchanger further comprises a fluid conduit at least partially disposed within the heat exchanger, the heat exchanger further comprising a substantially flat upper surface to which the photovoltaic receiver is mounted.

34. The solar photovoltaic concentrator panel of claim 33, further comprising a fluid pump in fluid communication with the fluid conduit.

35. The solar photovoltaic concentrator panel of claim 33, further comprising a fluid distribution system in fluid communication with the fluid conduit.

36. A solar photovoltaic concentrator panel, comprising:
a. a container, the container further comprising:
i. a top; the top comprising a transparent window; and
ii. a bottom dimensioned and configured as a passively cooled heat sink dimensioned and configured to dissipate waste heat to an ambient environment by at least one of convection and radiation;
iii. the top and bottom defining a plurality of ends;
b. a free-standing Fresnel lens concentrator disposed within the container at a fixed position relative to a first interior dimension of the container, the Fresnel lens concentrator optically forming a focal region of concentrated sunlight within the container; and
c. a photovoltaic receiver, the photovoltaic receiver comprising a photovoltaic cell, the photovoltaic receiver disposed within the container and attached to the bottom at a fixed position relative to a centerline of the lens such that a focal region of concentrated sunlight from the Fresnel lens concentrator substantially coincides with the photovoltaic receiver.

37. The solar photovoltaic concentrator panel of claim 36, further comprising a plurality of end supports dimensioned and configured to support the free-standing Fresnel lens concentrator.

38. The solar photovoltaic concentrator panel of claim 37, wherein the end supports are further configured to provide an end-to-end tensioning force into the free-standing Fresnel lens concentrators.

39. The solar photovoltaic concentrator panel of claim 37, wherein the end supports comprise a substantially arched end disposed proximate to the free-standing Fresnel lens concentrator.

40. A solar photovoltaic concentrator panel, comprising:
a. a container, the container further comprising:
i. a top, the top comprising a transparent window; and
ii. a bottom dimensioned and configured as a passively cooled heat sink dimensioned and configured to dissipate waste heat from a photovoltaic cell to an ambient environment by convection and radiation;
iii. the top and bottom defining a plurality of ends;
b. a plurality of polymeric Fresnel lens optical concentrators disposed within the container, each polymeric Fresnel lens optical concentrator being disposed at a predetermined position relative to a first interior dimension of the container, each polymeric Fresnel lens concentrator optically forming a focal region of concentrated sunlight within the container; and
c. a plurality of photovoltaic receivers, each disposed within the container and attached to the bottom, each photovoltaic receiver being disposed at a predetermined position relative to a centerline of a corresponding one of the polymeric Fresnel lens concentrators such that the focal region of concentrated sunlight from each polymeric Fresnel lens concentrator substantially coincides with a corresponding photovoltaic receiver, each photovoltaic receiver further comprising a photovoltaic cell; and
d. a lens support dimensioned and configured to independently connect a predetermined polymeric Fresnel lens concentrator to the bottom proximate to its corresponding photovoltaic receiver and to support and align the polymeric Fresnel lens concentrator such that its focal region remains substantially coincident with its associated photovoltaic receiver.

41. The solar photovoltaic concentrator panel of claim 40 further comprising a plurality of sides and end plates disposed intermediate the top and bottom, the top, sides, end plates, and bottom comprising a substantially non-flammable material.

42. A solar photovoltaic concentrator panel, comprising:
a. a container, the container further comprising:
i. a top, the top comprising a transparent window;
ii. a bottom;
iii. a plurality of sides disposed at outer boundaries of the container intermediate the top and bottom;
iv. a plurality of end plates disposed at outer boundaries of the container intermediate the top and bottom;
v. the bottom, sides, and end plates further dimensioned and configured to enclose a predetermined volume of the container beneath the window;
b. a Fresnel lens optical concentrator disposed within the container at a predetermined position relative to a first interior dimension of the container, the Fresnel lens concentrator optically forming a focal ,region of concentrated sunlight within the container;
c. a fluid cooled heat sink further comprising a fluid conduit, the fluid cooled heat sink attached to the bottom;
d. a photovoltaic receiver disposed within the container, the photovoltaic receiver operatively in communication with the fluid cooled heat sink, the photovoltaic receiver and the heat sink being further disposed at a predetermined position relative to a centerline of the corresponding lens such that a focal region of concentrated sunlight from the Fresnel lens optical concentrator substantially coincides with a corresponding photovoltaic receiver, the photovoltaic receiver further comprising a photovoltaic cell; and
e. a support dimensioned and configured to independently connect the Fresnel lens optical concentrator to the heat sink of its corresponding photovoltaic receiver and to support and align the Fresnel lens optical concentrator such that its focal region remains substantially coincident with the photovoltaic receiver.

43. The solar photovoltaic concentrator panel of claim 42, wherein the fluid is a liquid.

44. The solar photovoltaic concentrator panel of claim 43, further comprising a pump in fluid communication with the liquid.
